(19) United States
(12) Patent Application Publication
(10) Pub. No.: US 2006/0189055 A1
(43) Pub. Date: Aug. 24, 2006

(54) Method of forming a composite layer, method of manufacturing a gate structure by using the method of forming the composite layer and method of manufacturing a capacitor by using the method of forming the composite layer

(75) Inventors: Hong-Bae Park, Seoul (KR); Hag-Ju Cho, Seoul (KR); Yu-Gyun Shin, Seongnam-si (KR); Sang-Bom Kang, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/356,399

(22) Filed: Feb. 16, 2006

(30) Foreign Application Priority Data
Feb. 24, 2005 (KR) 10-2005-0015224

(51) Int. Cl. H01L 21/8234; H01L 21/336

(52) U.S. Cl. 438/197; 977/891

(57) ABSTRACT

Methods of forming a composite layer, a gate structure and a capacitor are disclosed. In the methods, a first dielectric layer is atomic layer deposited on a substrate by using an oxidation gas and a first precursor gas that includes hafnium precursors. A second dielectric layer is then atomic layer deposited on the first dielectric layer by using a nitriding gas and a second precursor gas that includes hafnium precursors.

### CROSS REFERENCE TO RELATED APPLICATION

This application claims the priority of Korean Patent Application No.10-2005-0015224, filed on Feb. 24, 2005, in the Korean Intellectual Property Office, the disclosure of which is incorporated herein in its entirety by reference.

### FIELD OF THE INVENTION

This invention relates to methods of forming a composite layer, and more particularly, to methods of forming a composite dielectric layer by atomic layer deposition.

### BACKGROUND OF THE INVENTION

It is known to use material having a substantially high dielectric constant(i.e. high-k material) for a gate insulation layer of a metal oxide semiconductor (MOS) transistor, a dielectric layer of a capacitor, a gate dielectric layer of a non-volatile memory device and/or other microelectronic device applications. The high-k material can reduce a leakage current and/or provide a relatively thin thickness. In addition, an equivalent oxide thickness (EOT) of a dielectric structure including the high-k material is substantially thin.

For example, the high-k material can be a hafnium oxide (HfO₂) layer. A method of forming the hafnium oxide layer is disclosed in U.S. Pat. No. 6,348,386 issued to Gilmer.

However, because a crystallization of hafnium oxide may be initiated at a temperature of about 300° C. while the hafnium oxide layer is formed, leakage current through the hafnium oxide layer may increase. Moreover, if a gate conductive layer of poly-silicon doped with impurities such as boron is formed on a gate insulation layer of hafnium oxide, the impurities included in the gate conductive layer may penetrate the gate insulation layer to be diffused into a channel region positioned under the gate insulation layer. Thus, a carrier mobility of the channel region may rapidly decrease.

For these and other reasons, hafnium silicon oxide (HfSiO) may be used as the material having the substantially high dielectric constant instead of hafnium oxide. In particular, hafnium silicon oxide can have good electrical characteristics substantially similar to those of silicon oxide.

A hafnium silicon oxide layer may be formed by a sputtering process, a chemical vapor deposition process or an atomic layer deposition process. When the hafnium oxide layer is formed by the sputtering process, mass production of the hafnium oxide layer may be hard to achieve. When the hafnium oxide layer is formed by the chemical vapor deposition process, hafnium content and a silicon content of the hafnium silicon oxide layer may be easily controlled, but it may be difficult to form thin hafnium oxide layers, e.g., below about 50 Å. However, when the hafnium oxide layer is formed by the atomic layer deposition process, the hafnium content and the silicon content of the hafnium silicon oxide layer may be well controlled. In addition, the thickness of the hafnium oxide layer may be efficiently controlled. Furthermore, step coverage of the hafnium oxide layer may be satisfactory.

For example, conventional methods of forming the hafnium silicon oxide layer by using the atomic layer deposition process are disclosed in U.S. Patent Application Publication No. 2003-232506, Japanese Patent Laid-Open Publication No. 2003-347297, Korean Patent Laid-open Publication No. 2002-32054 and Korean Patent Laid-Open Publication No. 2002-91743.

In U.S. Patent Application Publication No. 2003-232506, the hafnium silicon oxide layer is formed by using tetrakis diethyl amino hafnium (TDEAH) and tetrakis diethyl amino silicon (TDMAS) as a hafnium precursor and a silicon precursor, respectively.

In Japanese Patent Laid-Open Publication No. 2003-347297, the hafnium silicon oxide layer is formed by using TDEAH and tetra methoxy silane (TMOS) as a hafnium precursor and a silicon precursor, respectively. In addition, in performing the atomic layer deposition process, the number of times TDEAH is introduced and the number of times TMOS is introduced are adjusted to control a hafnium content and a silicon content of the hafnium silicon oxide layer.

In Korean Patent Laid-Open Publication No. 2002-32054, the hafnium silicon oxide layer is formed by reacting a hafnium oxide layer with a silicon compound such as silane (SiH₄), disilane (Si₂H₆) or diclorosilane (SiCl₂H₂).

The above-described hafnium silicon oxide layer can allow improved carrier mobility and/or on/off current characteristic in comparison with the hafnium oxide layer. However, impurities may still easily penetrate the hafnium silicon oxide layer.

In order to reduce or prevent penetration of the impurities, nitrogen may be diffused into the hafnium oxide layer or the hafnium silicon oxide layer. Particularly, the hafnium oxide layer or the hafnium silicon oxide layer is formed. The hafnium oxide layer and the hafnium silicon oxide layer are then thermally treated in an ammonia (NH₃) atmosphere to form a hafnium oxynitride layer or a hafnium silicon oxynitride layer.

For example, methods of forming the hafnium oxynitride layer or the hafnium silicon oxynitride layer are disclosed in U.S. Patent Application Publication No. 2004-132315 and U.S. Pat. No. 6,717,226.

However, it may be difficult to control a nitrogen content of the hafnium silicon oxynitride layer. In addition, nitrogen included in the hafnium silicon oxynitride layer may easily diffuse into a channel region so that carrier mobility of the channel region can be deteriorated. Furthermore, because the hafnium silicon oxynitride layer is formed by performing a nitriding process on the hafnium oxide layer that is already formed, a time required for forming the hafnium silicon oxynitride layer may be increased.

### SUMMARY OF THE INVENTION

In accordance with some embodiments of the present invention, there are provided methods of manufacturing a composite layer. In these methods, a first dielectric layer is formed on a substrate by atomic layer deposition using an oxidation gas and a first precursor gas that includes hafnium precursors. A second dielectric layer is formed on the first dielectric layer by atomic layer deposition using a nitriding gas and a second precursor gas that includes hafnium precursors. The first and second precursor gases may be same or different from one another.

The first dielectric layer may include hafnium oxide. In order to form the first dielectric layer, the hafnium precursors included in the first precursor gas may be supplied onto the substrate. First and second portions of the hafnium precursors are absorbed to the substrate. The first portion is chemically absorbed to the substrate. The second portion is physically absorbed to the substrate. The oxidation gas is supplied onto the substrate. The first dielectric layer including hafnium oxide is formed on the substrate by reacting the oxidation gas with the first portion of the hafnium precursors.

Examples of the hafnium precursor may include Hf[N(CH₃)₂]₄, Hf[N(C₂H₅)CH₃]₄, Hf[N(C₂H₅)₂]₄, Hf[OC(CH₃)₂CH₂OCH₃]₄, Hf[OC(CH₃)₃]₄, etc. These materials may be used alone or in combination thereof

The second dielectric layer may include hafnium oxide. In order to form the second dielectric layer, the hafnium precursors included in the second precursor gas are supplied onto the first dielectric layer. First and second portions of the hafnium precursors are absorbed to the first dielectric layer. The first portion is chemically absorbed to the first dielectric layer. The second portion is physically absorbed to the first dielectric layer. The nitriding gas is supplied onto the substrate. The second dielectric layer including hafnium oxide is formed on the first dielectric layer by reacting the nitriding gas with the first portion of the hafnium precursors.

The oxidation gas may be an ozone gas, a water vapor gas, a hydrogen peroxide gas, a methanol gas and/or an ethanol gas. These gases may be used alone or in combination. The nitriding gas may be ammonium gas and/or a nitrogen (N₂) gas that is in a plasma state.

Processes for forming the first dielectric layer and processes for forming the second dielectric layer may be repeatedly performed to obtain a desired thickness. A profile of nitrogen in the composite layer may be efficiently controlled by controlling a thickness of the first dielectric layer, a thickness of the second dielectric layer and/or a supply time of the nitriding gas.

In accordance with other embodiments of the present invention, the first dielectric layer may include hafnium oxide. In order to form the first dielectric layer, the hafnium precursors included in the first precursor gas are supplied onto the substrate. First and second portions of the hafnium precursors are absorbed to the substrate. The first portion is chemically absorbed to the substrate. The second portion is physically absorbed to the substrate. The oxidation gas is supplied onto the substrate. A first solid material including hafnium oxide is formed on the substrate by reacting the oxidation gas with the first portion of the hafnium precursors. Silicon precursors are supplied onto the first solid material. First and second portions of the silicon precursors are absorbed to the first solid material. The first portion is chemically absorbed to the first solid material. The second portion is physically absorbed to the first solid material. The oxidation gas is supplied onto the first solid material. The second solid material including silicon oxide is formed on the first solid material by reacting the oxidation gas with the first portion of the silicon precursors.

Examples of the silicon precursor may include H₂N(CH₂)₃Si(OC₂H₅)₃, Si[N(CH₃)₂]₄, Si[N(C₂H₅)CH₃]₄, Si[N(C₂H₅)₂]₄, etc. These materials may be used alone or in combination thereof.

Processes for forming the first solid material and processes for forming the second solid material may be repeatedly performed to control a thickness of the composite layer and/or a dielectric constant of the composite layer.

In accordance with still other embodiments of the present invention, there are provided methods for manufacturing a gate structure. In these methods, a first insulation layer is formed on a substrate by atomic layer deposition using an oxidation gas and a first precursor gas that includes hafnium precursors. A second insulation layer is formed on the first insulation layer by atomic layer deposition using a nitriding gas and a second precursor gas that includes hafnium precursors to obtain a composite gate insulation layer including the first insulation layer and the second insulation layer. A gate conductive layer is formed on the composite gate insulation layer. The gate conductive layer and the composite gate insulation layer are patterned to form a gate electrode and a composite gate insulation layer pattern.

In accordance with still other embodiments of the present invention, there are provided methods of manufacturing a gate structure of a non-volatile memory device. In these methods, a tunnel dielectric layer is formed on a substrate. A floating gate conductive layer is formed on the tunnel dielectric layer. A first dielectric layer is formed on the floating gate conductive layer by atomic layer deposition using an oxidation gas and a first precursor gas that includes hafnium precursors. A second dielectric layer is formed on the first dielectric layer by atomic layer deposition using a nitriding gas and a second precursor gas that includes hafnium precursors to obtain a composite dielectric layer including the first dielectric layer and the second dielectric layer. A control gate conductive layer is formed on the composite gate dielectric layer. The control gate conductive layer, the composite gate dielectric layer, the floating gate conductive layer and the tunnel dielectric layer are sequentially patterned to form a control gate electrode, a composite gate dielectric layer pattern, a floating gate electrode and a tunnel dielectric layer pattern.

In accordance with still other embodiments of the present invention, there are provided methods of manufacturing a capacitor. In these methods, a lower electrode is formed on a substrate. A first dielectric layer is formed on the lower electrode by atomic layer deposition using an oxidation gas and a first precursor gas that includes hafnium precursors. A second dielectric layer is formed on the first dielectric layer by atomic layer deposition using a nitriding gas and a second precursor gas including hafnium precursors to obtain a composite dielectric layer including the first dielectric layer and the second dielectric layer. An upper electrode is formed on the composite dielectric layer.

Related dielectric structures also may be provided according to various embodiments of the present invention. These dielectric structures may include a substrate and a dielectric layer on the substrate. The dielectric layer comprises a first sublayer adjacent the substrate that comprises hafnium oxide and is free of nitrogen therein. A second sublayer remote from the substrate comprises hafnium oxide and includes nitrogen therein. Structures corresponding to all of the embodiments described above also may be provided according to other embodiments of the present invention.

According to embodiments of the present invention, a dielectric constant of a composite layer may be adjusted by controlling thicknesses of first and second dielectric layers. In addition, a desired profile of nitrogen in the composite layer may be obtained by controlling the thickness of the second dielectric layer, a supply time of a nitriding gas and/or a supply amount of the nitriding gas. For example, a position of nitrogen in the composite layer may be adjusted by controlling the thickness of the first dielectric layer. A nitrogen content of the composite layer may be adjusted by controlling the thickness of the second dielectric layer, the supply time of the nitriding gas and the supply amount of the nitriding gas.

### BRIEF DESCRIPTION OF THE DRAWINGS

FIGS. 1 to 8 are cross-sectional views illustrating methods of manufacturing a composite layer in accordance with some embodiments of the present invention;

FIG. 9 is a cross-sectional view illustrating methods of manufacturing a composite layer in accordance with other embodiments of the present invention;

FIG. 10 is a cross-sectional view illustrating methods of manufacturing a composite layer in accordance with still other embodiments of the present invention;

FIG. 11 is a cross-sectional view illustrating methods of manufacturing a composite layer in accordance with still other embodiments of the present invention;

FIGS. 12 and 13 are cross-sectional views illustrating methods of manufacturing a composite layer in accordance with still other embodiments of the present invention;

FIGS. 14 and 15 are cross-sectional views illustrating methods of manufacturing a gate structure in accordance with still other embodiments of the present invention;

FIG. 16 is a graph illustrating capacitance of a gate structure manufactured by the methods illustrated in FIGS. 14 and 15 and a conventional gate structure manufactured by a conventional method;

FIG. 17 is a graph illustrating leakage currents of the gate structure and the conventional gate structure;

FIGS. 18 and 19 are cross-sectional views illustrating methods of manufacturing a gate structure in accordance with still other embodiments of the present invention; and

FIG. 20 is a cross-sectional view illustrating methods of manufacturing a capacitor in accordance with still other embodiments of the present invention.

### DETAILED DESCRIPTION

Some embodiments of the present invention will be described with reference to the accompanying drawings. The present invention may, however, be embodied in many different forms and should not be construed as limited to the some embodiments set forth herein. Rather, the embodiments are provided so that disclosure of the present invention will be thorough and complete, and will fully convey the scope of the present invention to those skilled in the art. The principles and features of this invention may be employed in varied and numerous embodiments without departing from the scope of the present invention. In the drawings, the size and relative sizes of layers and regions may be exaggerated for clarity. The drawings are not to scale. Like reference numerals refer to like elements throughout.

It will be understood that when an element or layer is referred to as being “on”, “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the present specification and relevant art and will not be interpreted in an idealized and/or overly formal sense unless expressly so defined herein.

Some embodiments of the present invention are described with reference to cross-section illustrations that are schematic illustrations of idealized embodiments of the present invention. As such, variations from the shapes of the illustrations as a result, for example, of manufacturing techniques and/or tolerances, are to be expected. Thus, some embodiments of the present invention should not be construed as limited to the particular shapes of regions illustrated herein but are to include deviations in shapes that result, for example, from manufacturing. For example, a region illustrated as a rectangle will, typically, have rounded or curved features. Thus, the regions illustrated in the figures are schematic in nature of a device and are not intended to limit the scope of the present invention.

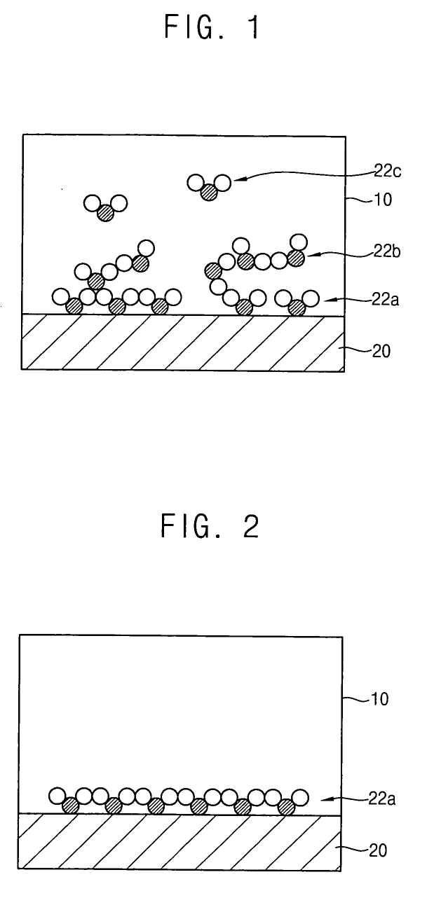

FIGS. 1 to 8 are cross-sectional views illustrating methods of manufacturing a composite layer in accordance with some embodiments of the present invention.

Referring to FIG. 1, a substrate 20 such as a silicon wafer is transferred into a chamber 10 used for performing an atomic layer deposition (ALD) process. A temperature of the chamber 10 may be maintained at about 150° C. to about 400° C. If the temperature of the chamber 10 is below about 150° C., the reaction materials supplied into the chamber 10 to form a composite layer 30 (see FIG. 8) on the substrate 20 may not be efficiently reacted with each other. On the other hand, if the temperature of the chamber 10 is above about 400° C., the composite layer 30 may be rapidly crystallized. Thus, in some embodiments, the temperature of the chamber 10 may be about 150° C. to about 400° C. As one example, the temperature of the chamber 10 may be about 250° C. to about 350° C. As another example, the temperature of the chamber 10 may be about 300° C. In some embodiments, the temperature of the chamber 10 is about 300° C., and the composite layer 30 may be formed on the substrate 20 by atomic layer deposition.

A first precursor gas including a hafnium precursor is supplied onto the substrate 20. Particularly, the first precursor gas may be supplied onto the substrate 20 with the aid of a carrier gas. The carrier gas may include argon and/or nitrogen. The first precursor gas may be supplied onto the substrate 20 by using a liquid delivery system (LDS) and/or a bubbler system. Examples of the hafnium precursor may include Hf[N(CH₃)₂]₄ (tetrakis dimethyl amino hafnium; TDMAH), Hf[N(C₂H₅)CH₃]₄ (tetrakis ethyl methyl amino hafnium; TEMAH), Hf[N(C₂H₅)₂]₄ (tetrakis diethyl amino hafnium; TDEAH), Hf[OC(CH₃)₂CH₂OCH₃]₄, Hf[OC(CH₃)₃]₄, etc. These hafnium precursors may be used alone or in a combination thereof. The hafnium precursor may be supplied onto the substrate 20 for about 0.5 second to about 3 seconds. For example, the hafnium precursor may be supplied onto the substrate 20 for about 2 seconds.

The hafnium precursors supplied onto the substrate 20 may be divided into a first portion 22a, a second portion 22b and a third portion 22c. The first portion 22a may be chemically absorbed to the substrate 20. The second portion 22b may be physically absorbed to the substrate 20 and/or the first portion 22b. The third portion 22c may float in the chamber 10.

Particularly, hafnium and/or nitrogen may be chemically absorbed to the substrate 20. Hafnium chemically absorbed to the substrate 20 may be supplied from the first portion 22a of the hafnium precursor. Nitrogen chemically absorbed to the substrate 20 may be supplied from the carrier gas and/or the first portion 22a of the hafnium precursor.

Referring to FIG. 2, a purge gas is supplied onto the substrate 20 to remove at least some of the second portion 22b and the third portion 22c. The purge gas may include argon and/or nitrogen. The purge gas may be supplied onto the substrate 20 for about 0.5 second to about 5 seconds. For example, the purge gas may be supplied onto the substrate 20 for about 2 seconds.

For example, when the hafnium precursor is TEMAH including a CH radical, hafnium and nitrogen, the CH radical of the second portion 22b may be detached from the substrate 20 and/or the first portion 22a so that the second portion 22b may be separated from the substrate 20 and/or the first portion 22a. Alternatively, a CH radical of the first portion 22a , the CH radical being absorbed to the second portion 22b , may be detached (or desorbed) from hafnium and/or nitrogen of the first portion 22a , hafnium and/or nitrogen being chemically absorbed to the substrate 20 so that the second portion 22b may be separated from the first portion 22a together with the CH radical of the first portion 22a. The second portion 22b separated from the substrate 20 and/or the first portion 22a may be exhausted from the chamber 10 together with the third portion 22c by using a vacuum pressure. However, hafnium and/or nitrogen included in the first portion 22 of the hafnium precursor may be still absorbed to the substrate 20.

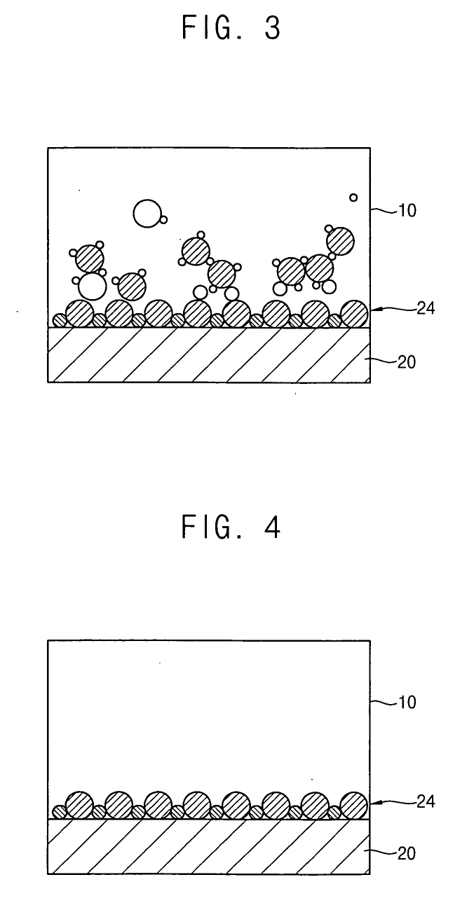

Referring to FIG. 3, an oxidation gas is supplied onto the substrate 20. The oxidation gas may be reacted with the first portion 22a of the hafnium precursor, the first portion being chemically absorbed to the substrate 20, to form a first dielectric layer 24 on the substrate 20. The first dielectric layer 24 may include hafnium oxide. Examples of the oxidation gas may be an ozone (O₃) gas, a water vapor (H₂O) gas, a hydrogen peroxide (H₂O₂) gas, a methanol (CH₃OH) gas, an ethanol (C₂H₅OH) gas, etc. These gases may be used alone or in a combination thereof.

In some embodiments, the ozone gas may be used as the oxidation gas. The ozone gas may be supplied onto the substrate 20 for about 1 second to about 5 seconds. For example, the ozone gas may be supplied onto the substrate 20 for about 3 seconds. Oxygen supplied from the ozone gas may substitute for nitrogen chemically absorbed to the substrate 20 so that nitrogen may be removed from the substrate 20. However, a substantially small amount of nitrogen may still remain on the substrate 20.

Referring to FIG. 4, the purge gas is supplied onto the substrate 20 so that an unused oxidation gas and a byproduct that is produced by a reaction between the first portion 22 of the hafnium precursor and the oxidation gas may be removed from the chamber 10. The purge gas may be supplied onto the substrate 20 for about 1 second to about 5 seconds. For example, the purge gas may be supplied onto the substrate 20 for about 3 seconds.

Processes for forming the first dielectric layer 24 may be repeatedly performed (at least twice) until a desired thickness of the first dielectric layer 24 is obtained.

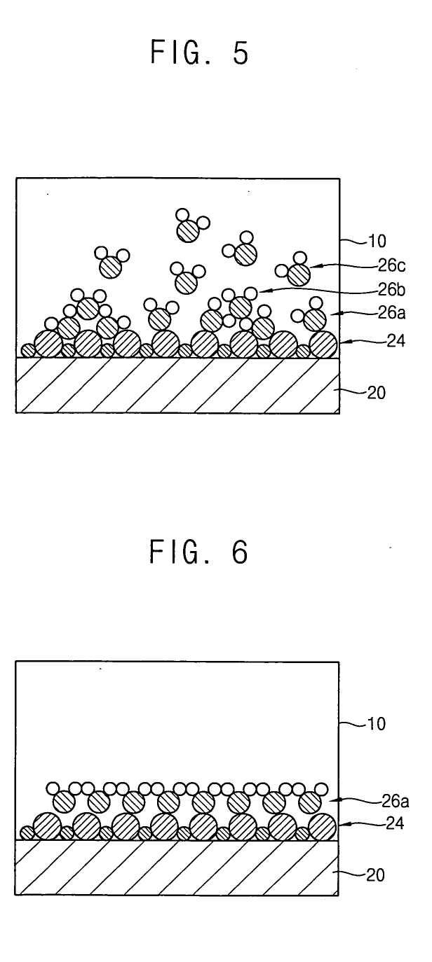

Referring to FIG. 5, a second precursor gas including hafnium precursors may be supplied onto the substrate 20. Particularly, the second precursor gas may be supplied onto the first dielectric layer 24 formed on the substrate 20. The second precursor gas may be substantially the same as the first precursor gas or it may be different therefrom.

The hafnium precursors included in the second precursor gas supplied onto the first dielectric layer 24 may be divided into a first portion 26a, a second portion 26b and a third portion 26c. The first portion 26a may be chemically absorbed to the first dielectric layer 24. The second portion 26b may be physically absorbed to the first dielectric layer 24 and/or the first portion 26b. The third portion 26c may float in the chamber 10.

The hafnium precursors may be supplied onto the first dielectric layer 24 by using a carrier gas for about 0.5 second to about 3 seconds. For example, the hafnium precursor may be supplied onto the first dielectric layer 24 for about 2 seconds.

Referring to FIG. 6, the purge gas is supplied onto the first dielectric layer 24 to remove the second portion 26b and the third portion 26c. The purge gas may include argon and/or nitrogen. The purge gas may be supplied onto the first dielectric layer 24 for about 0.5 second to about 5 seconds. For example, the purge gas may be supplied onto the first dielectric layer 24 for about 2 seconds.

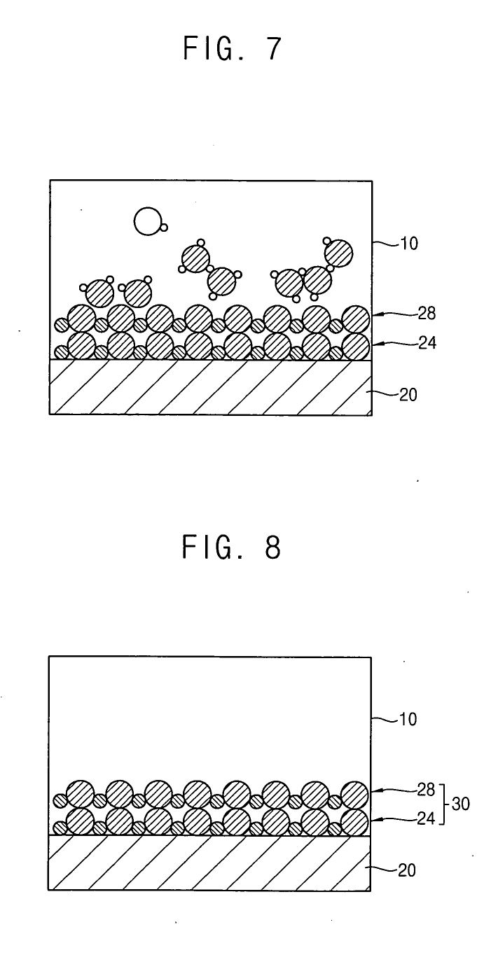

Referring to FIG. 7, a nitriding gas may be supplied onto the first dielectric layer 24 to which the first portion 26a is absorbed. The nitriding gas may be chemically reacted with the first portion 26a so that a second dielectric layer 28 that includes hafnium nitride may be formed on the first dielectric layer 24. The nitriding gas may be an ammonium (NH₃) gas and/or a nitrogen (N₂) gas in a plasma state. These gases may be used alone or in combination.

In some embodiments, the ammonium gas is used as the nitriding gas. The nitriding gas may be supplied onto the first dielectric layer 24 for about 1 second to about 5 seconds. For example, the ammonium gas may be supplied onto the first dielectric layer 24 for about 3 seconds.

Referring to FIG. 8, the purge gas is supplied onto the second dielectric layer 28 so that an unused nitriding gas and a byproduct that is produced by a reaction between the first portion 26a and the nitriding gas may be removed from the chamber 10. The purge gas may be supplied onto the second dielectric layer 28 for about 1 second to about 5 seconds. For example, the purge gas may be supplied onto the second dielectric layer 28 for about 3 seconds.

Processes for forming the second dielectric layer 28 may be repeatedly performed until a desired thickness of the second dielectric layer 28 is obtained. Thus, the composite layer 30 including the first dielectric layer 24 and the second dielectric layer 28 may be formed on the substrate 20.

The temperature of the chamber 10 may be maintained constant in forming a composite layer 30. Many apparent variations of supply rates and supply times of the hafnium precursor, the oxidation gas, the nitriding gas and the purge gas are possible. A dielectric constant of the composite layer 30 may vary in accordance with thicknesses of the first dielectric layer 24 and the second dielectric layer 28. A position of nitrogen included in the composite layer 30 may vary in accordance with the thickness of the first dielectric layer 24. A nitrogen content of the composite layer 30 may vary in accordance with the thickness of the second dielectric layer 28. The nitrogen content of the composite layer 30 may also vary in accordance with the supply rate and the supply time of the nitriding gas.

A desired dielectric constant and a desired nitrogen profile of the composite layer 30 may be obtained by varying process conditions in forming the first dielectric layer 24 and the second dielectric layer 28. In addition, the nitriding gas introduced into the chamber 10 to form the second dielectric layer 24 may further serve to reduce a carbon content of the composite layer 30 so that electrical characteristics of the composite layer 30 may be further improved.

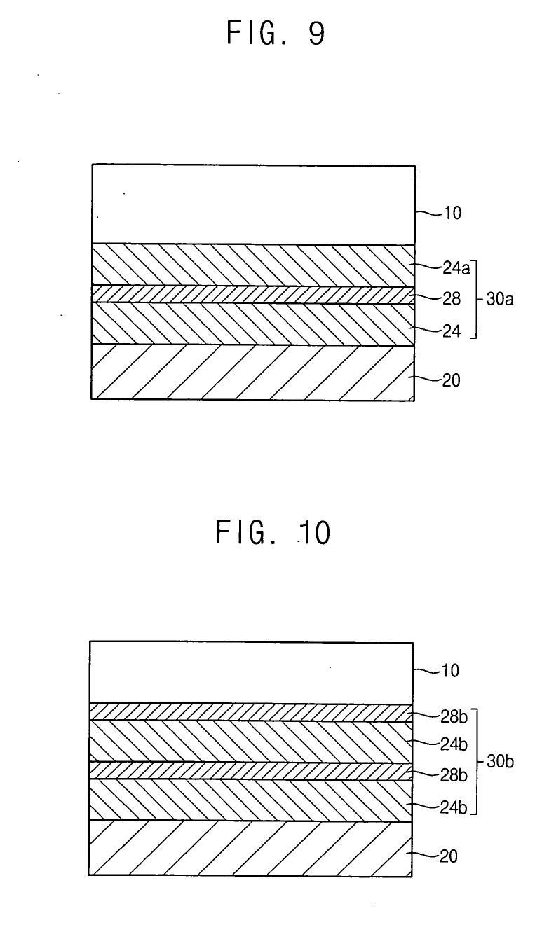

FIG. 9 is a cross-sectional view illustrating methods of manufacturing a composite layer in accordance with some embodiments of the present invention.

Referring to FIG. 9, a first dielectric layer 24 and a second dielectric layer 28 are serially formed on a substrate 20. Processes for forming the first dielectric layer 24 and the second dielectric layer 28 can be substantially the same as those already illustrated in FIGS. 1 to 8. Thus, any further explanations will not be repeated.

Thereafter, a third dielectric layer 24a is formed on the second dielectric layer 28 so that a composite layer 30a including the first dielectric layer 24, the second dielectric layer 28 and the third dielectric layer 24a is formed on the substrate 20. Electrical characteristics of the composite layer 30a may be satisfactory in virtue of the third dielectric layer 24a.

The third dielectric layer 24a can be substantially the same as the first dielectric layer 24. In addition, processes for forming the third dielectric layer 24a can be substantially the same as those for forming the first dielectric layer 24. Thus, any further explanations will not be repeated.

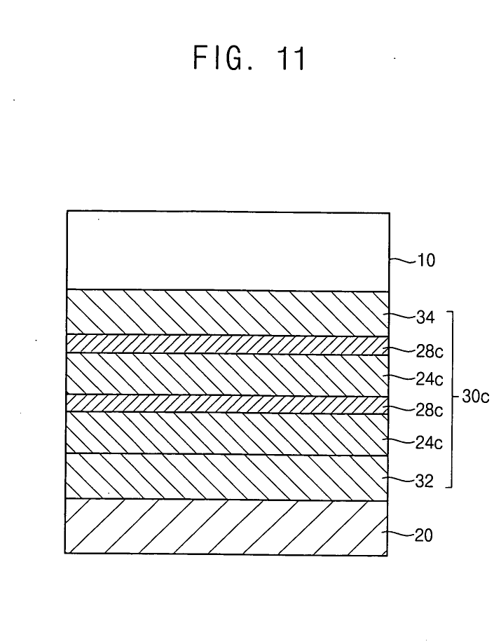

FIG. 10 is a cross-sectional view illustrating methods of manufacturing a composite layer in accordance with some embodiments of the present invention.

Referring to FIG. 10, a first dielectric layer 24b and a second dielectric layer 28b may be alternately formed on a substrate 20 at least twice. Thus, a composite layer 30b including the first dielectric layers 24b and the second dielectric layers 28b may be formed on the substrate 20. Because the first dielectric layer 24b and the second dielectric layer 28b are alternately formed on the substrate 20 at least twice, electrical characteristics of the composite layer 30b may be satisfactory.

The first dielectric layer 24b can be substantially the same as the first dielectric layer 24 already illustrated in FIG. 3. In addition, processes for forming the first dielectric layer 24b can be substantially the same as those for forming the first dielectric layer 24. Thus, any further explanation will not be repeated. The second dielectric layer 28b can be substantially the same as the second dielectric layer 28 already illustrated in FIG. 7. In addition, processes for forming the second dielectric layer 28b can be substantially the same as those for forming the second dielectric layer 28. Thus, any further explanation will not be repeated.

FIG. 11 is a cross-sectional view illustrating methods of manufacturing a composite layer in accordance with some embodiments of the present invention.

Referring to FIG. 11, a base dielectric layer 32 is formed on a substrate 20. The base dielectric layer 32 may include hafnium silicon oxide. The base dielectric layer 32 may be formed by an atomic layer deposition process using a hafnium precursor, a silicon precursor and an oxidation gas.

Particularly, the hafnium precursor and the oxidation gas are sequentially supplied onto the substrate 20 to form a first solid material including hafnium oxide. Thereafter, the silicon precursor and the oxidation gas are sequentially supplied onto the first solid material to form a second solid material including silicon oxide. Thus, the base dielectric layer 32 including hafnium silicon oxide is formed on the substrate.

Thereafter, a first dielectric layer 24c and a second dielectric layer 28c may be alternately formed on the base dielectric layer 32 at least once. The first dielectric layer 24c can be substantially the same as the first dielectric layer 24 already illustrated in FIG. 3. In addition, processes for forming the first dielectric layer 24c can be substantially the same as those for forming the first dielectric layer 24. Thus, any further explanation will not be repeated. The second dielectric layer 28c can be substantially the same as the second dielectric layer 28 already illustrated in FIG. 7. In addition, processes for forming the second dielectric layer 28c can be substantially the same as those for forming the second dielectric layer 28. Thus, any further explanations will not be repeated.

A capping dielectric layer 34 may be then formed on an uppermost second dielectric layer 28c which is positioned higher than any other second dielectric layer 28c. Particularly, the capping dielectric layer 34 may include hafnium silicon oxide. Processes for forming the capping dielectric layer 34 can be substantially the same as those for forming the base dielectric layer 32. Thus, any further explanations will not be repeated.

As a result, a composite layer 30c including the base dielectric layer 32, the first dielectric layers 24c, the second dielectric layers 28c and the capping layer 34 is formed on the substrate 20. Because the composite layer 30c has a multi-layered structure, electrical characteristics of the composite layer 30b may be satisfactory.

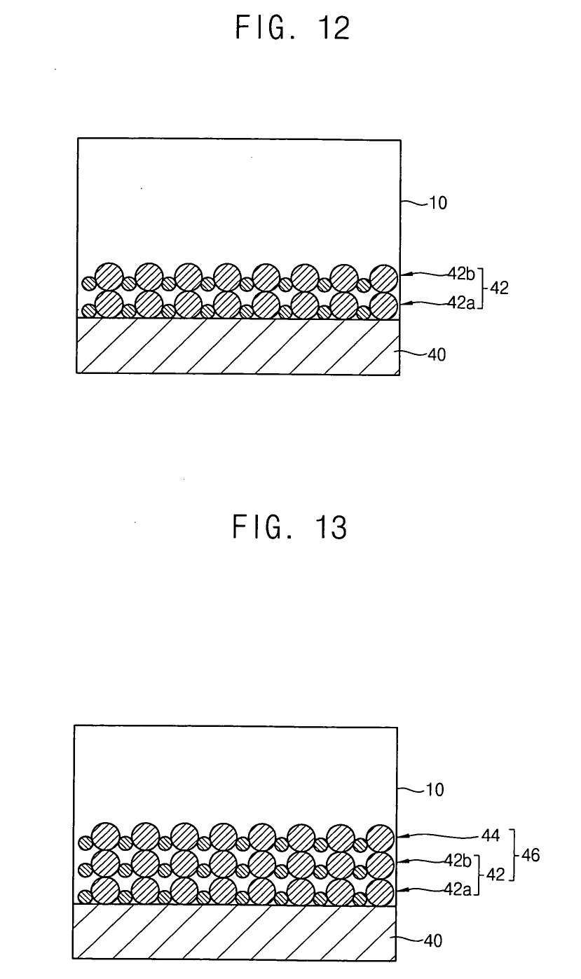

FIGS. 12 and 13 are cross-sectional views illustrating methods of manufacturing a composite layer in accordance with some embodiments of the present invention.

Referring to FIG. 12, a first dielectric layer 42 including hafnium silicon oxide may be formed on a substrate 40 such as a silicon wafer.

Particularly, the substrate 40 is transferred into a chamber 10 used for performing an atomic layer deposition process. A temperature of the chamber 10 may be maintained at about 150° C. to about 400° C. For example, the temperature of the chamber 10 may be maintained at about 300° C.

Hafnium precursors are supplied onto the substrate 40 by using a carrier gas. Examples of the hafnium precursor may be Hf[N(CH₃)₂]₄, Hf[N(C₂H₅)CH₃]₄, Hf[N(C₂H₅)₂]₄, Hf[OC(CH₃)₂CH₂OCH₃]₄, Hf[OC(CH₃)₃]₄, etc. These materials may be used alone or in a combination thereof. An argon gas and/or a nitrogen gas may be used as the carrier gas. The hafnium precursors may be supplied onto the substrate 40 for about 0.5 second to about 3 seconds. For example, the hafnium precursors may be supplied onto the substrate 40 for about 2 seconds.

The hafnium precursors may be divided into a first portion, a second portion and a third portion. The first portion may be chemically absorbed to the substrate 40. The second portion may be physically absorbed to the substrate 40 and/or the first portion. The third portion may float in the chamber 10.

A purge gas is then supplied onto the substrate 40 to remove at least some of the second portion and the third portion of the hafnium precursors. The purge gas may include argon and/or nitrogen. The purge gas may be supplied onto the substrate 40 for about 0.5 second to about 5 seconds. For example, the purge gas may be supplied onto the substrate 40 for about 2 seconds.

An oxidation gas is then supplied onto the substrate 40. The oxidation gas may be reacted with the first portion to form a first solid material 42a on the substrate 40. The first solid material 42a may include hafnium oxide. Examples of the oxidation gas may include an ozone (O₃) gas, a water vapor (H₂O) gas, a hydrogen peroxide (H₂O₂) gas, a methanol (CH₃OH) gas, an ethanol (C₂H₅OH) gas, etc. These gases may be used alone or in a combination thereof. The oxidation gas may be supplied onto the substrate 40 for about 1 second to about 5 seconds. For example, the oxidation gas may be supplied onto the substrate 40 for about 3 seconds.

The purge gas is then supplied onto the first solid material 42a to remove an unused oxidation gas and a byproduct that is produced by a reaction between the oxidation gas and the first portion of the hafnium precursors. The purge gas may be supplied onto the first solid material 42a for about 1 second to about 5 seconds. For example, the purge gas may be supplied onto the first solid material 42a for about 3 seconds.

Processes for forming the first solid material 42a may be repeatedly performed to increase a thickness of a first solid material film including the first solid material 42a. That is, a hafnium content of the composite layer 46 (see FIG. 13) may be adjusted by controlling the thickness of the first solid material film including the first solid material 42a.

Silicon precursors may be supplied onto the first solid material 42a. The silicon precursor may be supplied onto the first solid material 42a with the aid of a carrier gas. Examples of the silicon precursor may include H₂N(CH₂)₃Si(OC₂H₅)₃ (amino propyl triethoxy silane; APTES), Si[N(CH₃)₂]₄ (tetrakis dimethyl amino silicon; TDMAS), Si[N(C₂H₅)CH₃]₄ (tetrakis ethyl methyl amino silicon; TEMAS), Si[N(C₂H₅)₂]₄ (tetrakis diethyl amino silicon; TDEAS), etc. These materials may be used alone or in a combination thereof.

The silicon precursors may be divided into a first portion, a second portion and a third portion. The first portion may be chemically absorbed to the first solid material 42a. The second portion may be physically absorbed to the first solid material 42a and/or the first portion. The third portion may float in the camber 10. The silicon precursor may be supplied onto the first solid material 42a for about 0.5 second to about 3 seconds. For example, the silicon precursor may be supplied onto the first solid material 42a for about 2 seconds.

The purge gas may be then supplied onto the first solid material 42a to remove at least some of the second portion and the third portion of the silicon precursors from the chamber 10. The purge gas may be supplied onto the first solid material 42a for about 0.5 second to about 5 seconds. For example, the purge gas may be supplied onto the first solid material 42a for about 2 seconds.

Thereafter, an oxidation gas may be supplied onto the first solid material 42a to which the first portion of the silicon precursors is absorbed so that the first portion of the silicon precursors may be oxidized. Thus, a second solid material 42b including silicon oxide may be formed on the first solid material 42a.

The purge gas may be supplied onto the second solid material 42b to remove an unused oxidation gas and a byproduct that is produced a chemical reaction between the first portion of the silicon precursors and the oxidation gas from the chamber 10. The purge gas may be supplied onto the second solid material 42b for about 1 second to about 5 seconds. For example, the purge gas may be supplied onto the second solid material 42b for about 3 seconds.

Processes for forming the second solid material 42b may be repeatedly performed to increase a thickness of a second solid material film including the second solid material 42b. That is, a silicon content of the composite layer 46 (see FIG. 13) may be adjusted by controlling the thickness of the second solid material film including the second solid material 42b.

As a result, a first dielectric layer 42 including the first solid material 42a and the second solid material 42b may be formed on the substrate 20. The second solid material film may be continuously formed on the first solid material film. In addition, the thicknesses of the first and second solid material films may be controlled to obtain a desired thickness of the first dielectric layer 42.

Referring to FIG. 13, a second dielectric layer 44 including hafnium nitride may be formed on the first dielectric layer 42 including hafnium silicon oxide. The second dielectric layer 44 may be formed by an atomic layer deposition process using a hafnium precursor and a nitriding gas. The second dielectric layer 44 can be substantially the same as the second dielectric layer 28 already illustrated in FIGS. 7 and 8. In addition, processes for forming the second dielectric layer 44 can be substantially the same as those already illustrated in FIGS. 5 to 8. Thus, any further explanations will not be repeated.

As described above, amounts of hafnium, silicon and nitrogen that are included in the composite layer 46 may be efficiently adjusted. Thus, a dielectric constant and a nitrogen profile of the composite layer 46 may be efficiently controlled.

Although it is not particularly illustrated in the drawings, a third insulation layer substantially the same as the first dielectric layer 42 may be further formed on the second dielectric layer 44. In addition, the first dielectric layer 42 and the second dielectric layer 44 may be alternately deposited at least once to further improve electrical characteristics of the composite layer 46.

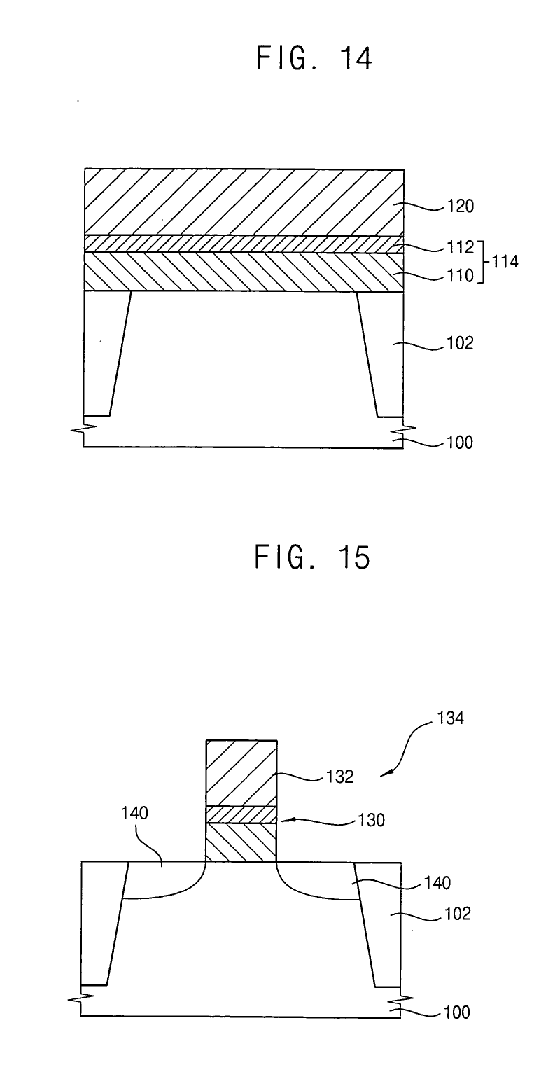

FIGS. 14 and 15 are cross-sectional views illustrating methods of manufacturing a gate structure in accordance with some embodiments of the present invention.

Referring to FIG. 14, a substrate 100 such as a silicon wafer is prepared. An isolation layer 102 is formed in a surface of the substrate 100 so that the substrate 100 may be divided into an active region and a field region.

Thereafter, a first insulation layer 110 is formed on the substrate 100 by an atomic layer deposition process using an oxidation gas and a first precursor gas that includes hafnium. A second insulation layer 112 is then formed on the first insulation layer 110 by an atomic layer deposition process using a nitriding gas and a second precursor gas that includes hafnium. Thus, a composite gate insulation layer 114 includes the first insulation layer 110 and the second insulation layer 112 may be formed on the substrate 100. The composite gate insulation layer 114 may include at least one first insulation layer 110 and at least one second insulation layer 112. That is, the first insulation layer 110 and the second insulation layer 112 may be alternately formed on the substrate 100 at least once to form the composite gate insulation layer 114.

In addition, in forming the composite gate insulation layer 114, thicknesses of the first insulation layer 110 and the second insulation layer 112 may be adjusted to enable the composite gate insulation layer 114 to have a desired nitrogen profile and a desired dielectric constant. Processes for forming the composite gate insulation layer 114 can be substantially the same as those for forming the composite layer 42 already illustrated in FIGS. 1 to 13. Thus, any further explanation will not be repeated.

A gate conductive layer 120 may be formed on the composite gate insulation layer 114. The gate conductive layer 120 may include a poly-silicon doped with impurities such as boron. The gate conductive layer 120 may be formed by a low pressure chemical vapor deposition (LPCVD) process. In addition, the gate conductive layer 120 may further include a metal silicide. In some embodiments, the gate conductive layer 120 may include a metal and/or a metal nitride.

Referring to FIG. 15, the gate conductive layer 120 and the composite layer 114 formed on the substrate 100 may be patterned so that a gate structure 143 including a composite gate insulation layer pattern 130 and a gate electrode 132 may be formed on the substrate 100. Particularly, the gate structure 134 may be formed by an anisotropic etching process using an etch mask (not shown). A source/drain region may be then formed in a portion of the surface of the substrate 100, the portion being adjacent to the gate structure 134. In addition, a gate spacer (not shown) may be further formed on a sidewall of the gate structure 134.

As described above, the composite gate insulation layer pattern 130 may be included in the gate structure 134. Thus, the composite gate insulation layer pattern 130 may reduce or prevent impurities such as boron from being diffused into a channel region positioned under the composite gate insulation layer pattern 130. In addition, a leakage current may be efficiently reduced or prevented with the aid of the composite gate insulation layer pattern 130. Furthermore, a diffusion of nitrogen into the channel region may be efficiently reduced or prevented by controlling a nitrogen content of the composite gate insulation layer pattern 130 as well as a position of nitrogen included in the composite gate insulation layer pattern 130. Thus, electrical characteristics such as carrier mobility may be improved.

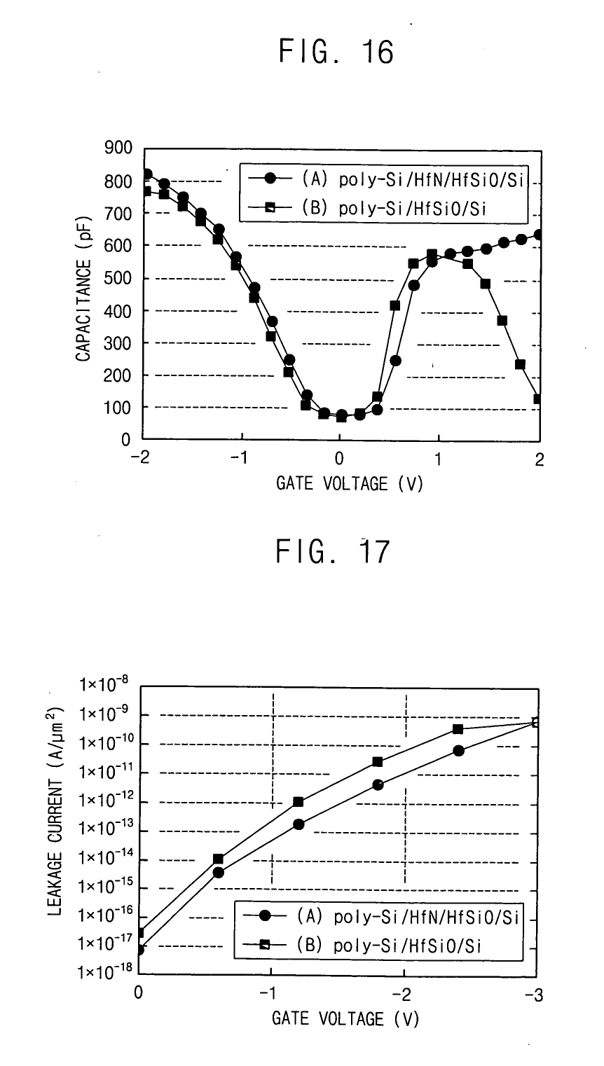

FIG. 16 is a graph illustrating capacitance of a gate structure manufactured by the methods illustrated in FIGS. 14 and 15 and a conventional gate structure manufactured by a conventional method. FIG. 17 is a graph illustrating leakage currents of the gate structure and the conventional gate structure.

Particularly, a first dielectric layer including hafnium silicon oxide was formed on the substrate. A second dielectric layer including hafnium nitride was formed on the first dielectric layer. Thus, a composite gate dielectric layer including the first dielectric layer and the second dielectric layer was formed on the substrate. Here, a thickness of the first dielectric layer was about 25Å. A thickness of the second dielectric layer was about 5Å. Thereafter, a gate conductive layer including doped poly-silicon was formed on the composite gate dielectric layer. The gate conductive layer and the composite gate dielectric layer were patterned to form a gate conductive layer pattern and a composite gate dielectric layer pattern. Thus, a first gate structure A including the gate conductive layer pattern and the composite gate dielectric layer pattern was formed on the substrate.

On the other hand, a second gate structure B including a gate conductive layer pattern and a conventional gate insulation layer pattern including hafnium silicon oxide were formed on a substrate. Here, the conventional gate insulation layer pattern was formed by using the conventional method. The thickness of the conventional gate insulation layer was about 30Å. The gate conductive layer pattern of the second gate structure B was formed by processes substantially the same as those for forming the gate conductive layer pattern of the first gate structure A.

Referring to FIG. 16, in case that a gate voltage was below about 1V, a capacitance of the first gate structure A was substantially the same as that of the second gate structure B at a certain voltage. However, in case that the gate voltage was above about 1V, the capacitance of the first gate structure A was substantially larger than that of the second gate structure B at a certain voltage. That is, when the gate voltage became large, a difference in capacitance between the first gate structure A and the second gate structure B increased.

Referring to FIG. 17, a leakage current of the first gate structure A was lower than that of the second gate structure B by about 10 A/μm².

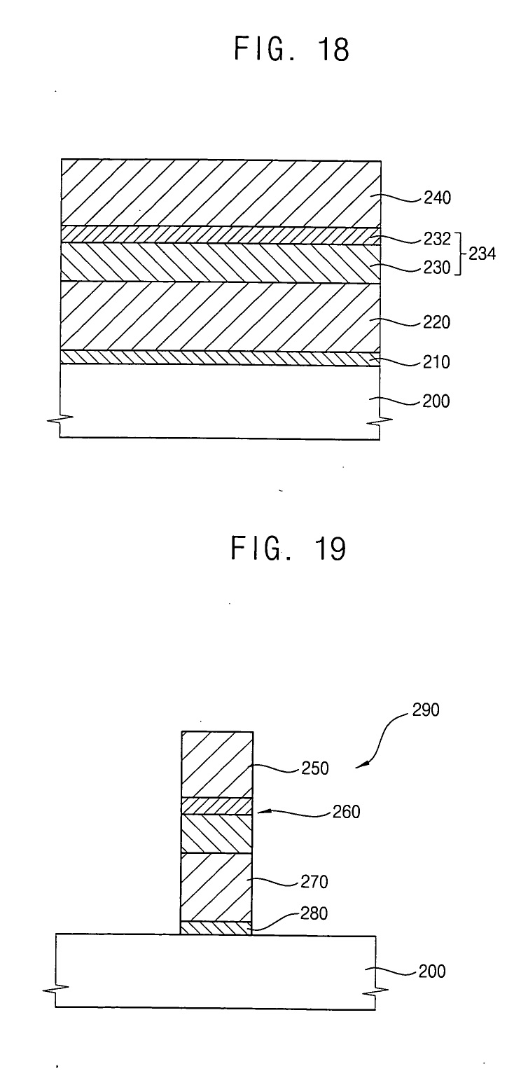

FIGS. 18 and 19 are cross-sectional views illustrating methods of manufacturing a gate structure in accordance with some embodiments of the present invention.

Referring to FIG. 18, a tunnel dielectric layer 210 is formed on a substrate 20 such as a silicon wafer. Particularly, the tunnel dielectric layer 210 may be a silicon oxide layer formed by a thermal oxidation process.

A floating gate conductive layer 220 is then formed on the tunnel dielectric layer 210. The floating gate conductive layer 220 may be formed using poly-silicon doped with impurities. The floating gate conductive layer 220 may be formed by a low pressure chemical vapor deposition (LPCVD) process.

A first dielectric layer 230 is then formed on the floating gate conductive layer 220. The first dielectric layer 230 may be formed by an atomic layer deposition (ALD) process using an oxidation gas and a first precursor gas that includes hafnium. Thereafter, a second dielectric layer 232 is formed on the first dielectric layer 230 by using an atomic layer deposition process that uses a nitriding gas and a second precursor gas that includes hafnium. Thus, a composite gate dielectric layer 234 including the first dielectric layer 230 and the second dielectric layer 232 may be formed on the floating gate conductive layer 220.

The above-described processes for forming the composite gate dielectric layer 234 can be substantially the same as those already illustrated in FIGS. 1 to 13. Thus, any further explanations will not be repeated.

A control gate conductive layer 240 is then formed on the composite gate dielectric layer 234. The control gate conductive layer 240 may be formed using poly-silicon doped with impurities. In some embodiments, the control conductive layer 240 may include a poly-silicon film doped with the impurities and a metal silicide film formed on the poly-silicon film. In some embodiments, the control gate conductive layer 240 may include metal and/or metal nitride.

Referririg to FIG. 19, the control gate conductive layer 240, the composite gate dielectric layer 234, the floating gate conductive layer 220 and the tunnel dielectric layer 210 are sequentially patterned to form a gate structure 290 of a non-volatile memory on the substrate 20. The gate structure 290 may include a control gate electrode 250, a composite gate dielectric layer pattern 260, a floating gate electrode 270 and a tunnel dielectric layer pattern 280. The gate structure 290 may be formed by an anisotropic etching process using an etch mask (not shown). A source/drain region (not shown) may be formed at a portion of a surface of the substrate 200, the portion being adjacent to the gate structure 290. Thus, the non-volatile memory device may be manufactured.

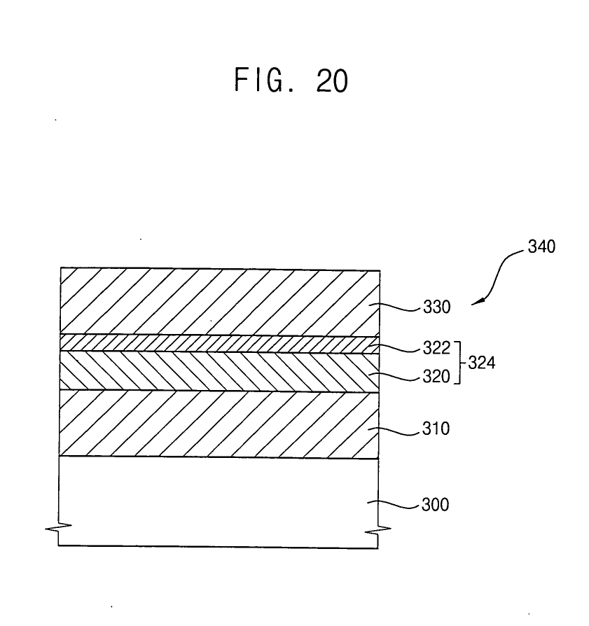

FIG. 20 is a cross-sectional view illustrating methods of manufacturing a capacitor in accordance with some embodiments of the present invention.

Referring to FIG. 20, a substrate 300 such as a silicon wafer is prepared. The substrate 300 may include semiconductor structures (not shown) such as a gate structure, a source/drain region and a bit line.

A lower electrode 310 is then formed on the substrate 300 where the semiconductor structures are formed. The lower electrode 310 may be formed using poly-silicon doped with impurities. The lower electrode 310 may be formed be a low pressure chemical vapor deposition process. In some embodiments, the lower electrode 310 may be formed using metal and/or metal nitride. Although it is not particularly illustrated in the drawings, the lower electrode 310 may have a cylindrical shape. In case that the lower electrode 310 has the cylindrical shape, electrical characteristics of the lower electrode 310 may be improved. For example, an effective area of the lower electrode 310 may be increased.

A first dielectric layer 320 is formed on the lower electrode 310 by an atomic layer deposition process using an oxidation gas and a first precursor gas including hafnium. A second dielectric layer 322 is then formed on the first dielectric layer 320 by an atomic layer deposition process using a nitriding gas and a second precursor gas that includes hafnium. Thus, a composition dielectric layer 324 including the first dielectric layer 320 and the second dielectric layer 322 may be formed on the lower electrode 310. The composite dielectric layer 324 may be formed by processes substantially the same as those already illustrated in FIGS. 1 to 13. Thus, any further explanations will not be repeated.

An upper electrode 330 may be formed on the composite dielectric layer 324 so that a capacitor 340 may be manufactured. The upper electrode 330 may be formed by using poly-silicon doped with impurities. Alternatively, the upper electrode 330 may be formed using metal and/or metal nitride.

According to some embodiments of the present invention, a profile of nitrogen in a composite layer may be controlled by adjusting a thickness of a first dielectric layer including hafnium oxide or hafnium silicon oxide, a thickness of a second dielectric layer including hafnium nitride, a supply time of a nitriding gas and a supply amount of the nitriding gas. In some embodiments, the composite dielectric layer comprises a first sublayer adjacent the substrate that comprises hafnium oxide and is free of nitrogen therein, and a second sublayer remote from the substrate that comprises hafnium oxide and includes nitrogen therein.

Thus, in case that the composite layer is employed as a gate insulation layer of a gate structure, impurities in a gate electrode may hardly penetrate the gate insulation layer. Thus, the impurities may not be diffused into a channel region. In addition, nitrogen may be hardly diffused into the channel region. Furthermore, a leakage current through the gate insulation layer may be efficiently reduced.

In addition, in case that the composite layer is used as either a control gate dielectric layer of a non-volatile memory device or a dielectric layer of a capacitor, a penetration of impurities and a leakage current may be efficiently reduced. In addition, an equivalent oxide thickness may be efficiently reduced.

As a result, the composite layer may be advantageously employed in a MOS transistor, the capacitor or the non-volatile memory device to improve electrical characteristics of the MOS transistor, the capacitor or the non-volatile memory device.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of manufacturing a composite layer, the method comprising:
atomic layer depositing a first dielectric layer on a substrate using an oxidation gas and a first precursor gas that includes hafnium precursors; and
atomic layer depositing a second dielectric layer on the first dielectric layer using a nitriding gas and a second precursor gas that includes hafnium precursors.

2. The method of claim 1, wherein the first dielectric layer includes hafnium oxide.

3. The method of claim 2, wherein atomic layer depositing the first dielectric layer comprises:
supplying the hafnium precursors included in the first precursor gas onto the substrate;
absorbing first and second portions of the hafnium precursors to the substrate, the first portion being chemically absorbed to the substrate, the second portion being physically absorbed to the substrate;
supplying the oxidation gas onto the substrate; and
forming the first dielectric layer including hafnium oxide on the substrate by reacting the oxidation gas with the first portion of the hafnium precursors.

4. The method of claim 3, wherein the hafnium precursors comprise Hf[N(CH₃)₂]₄, Hf[N(C₂H₅)CH₃]₄, Hf[N(C₂H₅)₂]₄, Hf[OC(CH₃)₂CH₂OCH₃]₄ and/or Hf[OC(CH₃)₃]₄.

5. The method of claim 3, wherein supplying the hafnium precursors, absorbing the first and second portions of the hafnium precursors, supplying the oxidation gas and forming the first dielectric layer are performed at least once.

6. The method of claim 2, further comprising forming a third dielectric layer substantially the same as the first dielectric layer on the second dielectric layer.

7. The method of claim 2, further comprising:
forming a third dielectric layer substantially the same as the first dielectric layer on the second dielectric layer; and
forming a fourth dielectric layer substantially the same as the second dielectric layer on the third dielectric layer.

8. The method of claim 7, wherein forming the third dielectric layer and forming the fourth dielectric layer are performed at least once.

9. The method of claim 2, further comprising atomic layer depositing a base dielectric layer including hafnium silicon oxide on the substrate by using an oxidation gas, a hafnium precursor and a silicon precursor before atomic layer depositing the first dielectric layer.

10. The method of claim 2, further comprising atomic layer depositing a capping layer including hafnium oxide on the second dielectric layer using an oxidation gas, a hafnium precursor and a silicon precursor.

11. The method of claim 1, wherein atomic layer depositing the second dielectric layer comprises:
supplying the hafnium precursors included in the second precursor gas onto the first dielectric layer;
absorbing first and second portions of the hafnium precursors to the first dielectric layer, the first portion being chemically absorbed to the first dielectric layer, the second portion being physically absorbed to the first dielectric layer;
supplying the nitriding gas onto the substrate; and
forming the second dielectric layer including hafnium oxide on the first dielectric layer by reacting the nitriding gas with the first portion of the hafnium precursors.

12. The method of claim 11, wherein supplying the hafnium precursors, absorbing first and second portions of the hafnium precursors, supplying the nitriding gas and forming the second dielectric layer are performed at least once.

13. The method of claim 1, wherein the oxidation gas comprises an ozone gas, a water vapor gas, a hydrogen peroxide gas, a methanol gas and/or an ethanol gas.

14. The method of claim 1, wherein the nitriding gas comprises an ammonium gas and/or a nitrogen (N₂) gas that has a plasma state.

15. The method of claim 1, wherein atomic layer depositing the first dielectric layer and atomic layer depositing the second dielectric layer are performed at a temperature of about 150° C. to about 400° C.

16. The method of claim 1, wherein the first dielectric layer includes hafnium silicon oxide.

17. The method of claim 16, wherein atomic layer depositing the first dielectric layer comprises:
supplying the hafnium precursors included in the first precursor gas onto the substrate;
absorbing first and second portions of the hafnium precursors to the substrate, the first portion being chemically absorbed to the substrate, the second portion being physically absorbed to the substrate;
supplying the oxidation gas onto the substrate; and
forming a first solid material including hafnium oxide on the substrate by reacting the oxidation gas with the first portion of the hafnium precursors;
supplying silicon precursors onto the first solid material;
absorbing first and second portions of the silicon precursors to the first solid material, the first portion being chemically absorbed to the first solid material, the second portion being physically absorbed to the first solid material;
supplying the oxidation gas onto the first solid material; and
forming a second solid material including silicon oxide on the first solid material by reacting the oxidation gas with the first portion of the silicon precursors.

18. The method of claim 17, wherein the silicon precursors comprise H₂N(CH₂)₃Si(OC₂H₅)₃, Si[N(CH₃)₂]₄, Si[N(C₂H₅)CH₃]₄ and/or Si[N(C₂H₅)₂]₄.

19. The method of claim 17, wherein supplying the hafnium precursors, absorbing first and second portions of the hafnium precursors, supplying the oxidation gas and forming the first solid material are performed at least twice.

20. The method of claim 17, wherein supplying silicon precursors, absorbing first and second portions of the silicon precursors, supplying the oxidation gas and forming the second solid material are performed at least once.

21. The method of claim 17, wherein supplying the hafnium precursors, absorbing first and second portions of the hafnium precursors, supplying the oxidation gas, forming the first solid material, supplying silicon precursors, absorbing first and second portions of the silicon precursors, supplying the oxidation gas and forming the second solid material are performed at least once.

22. A method of manufacturing a gate structure, the method comprising:
atomic layer depositing a first insulation layer on a substrate by using an oxidation gas and a first precursor gas that includes hafnium precursors;
atomic layer depositing a second insulation layer on the first insulation layer by using a nitriding gas and a second precursor gas that includes hafnium precursors to thereby obtain a composite gate insulation layer including the first insulation layer and the second insulation layer;
forming a gate conductive layer on the composite gate insulation layer; and
patterning the gate conductive layer and the composite gate insulation layer to form a gate electrode and a composite gate insulation layer pattern.

23. A method of manufacturing a gate structure, the method comprising:
forming a tunnel dielectric layer on a substrate;
forming a floating gate conductive layer on the tunnel dielectric layer;
atomic layer depositing a first dielectric layer on the floating gate conductive layer by using an oxidation gas and a first precursor gas that includes hafnium precursors;
atomic layer depositing a second dielectric layer on the first dielectric layer by using an nitriding gas and a second precursor gas that includes hafnium precursors to thereby obtain a composite dielectric layer including the first dielectric layer and the second dielectric layer;
forming a control gate conductive layer on the composite gate dielectric layer; and
sequentially patterning the control gate conductive layer, the composite gate dielectric layer, the floating gate conductive layer and the tunnel dielectric layer to form a control gate electrode, a composite gate dielectric layer pattern, a floating gate electrode and a tunnel dielectric layer pattern.

24. A method of manufacturing a capacitor, the method comprising:
forming a lower electrode on a substrate;
atomic layer depositing a first dielectric layer on the lower electrode by using an oxidation gas and a first precursor gas that includes hafnium precursors;
atomic layer depositing a second dielectric layer on the first dielectric layer by using a nitriding gas and a second precursor gas including hafnium precursors to obtain a composite dielectric layer including the first dielectric layer and the second dielectric layer; and
forming an upper electrode on the composite dielectric layer.
